(19) United States
(12) Patent Application Publication
(10) Pub. No.: US 2026/0082949 A1
(43) Pub. Date: Mar. 19, 2026

(54) SEMICONDUCTOR PACKAGE INCLUDING PAD LAYER AND METHOD OF MANUFACTURING THE SAME

(71) Applicant: Samsung Electronics Co., Ltd., Suwon-si (KR)

(72) Inventors: Seunghun CHAE, Suwon-si (KR); Unbyoung KANG, Suwon-si (KR)

(73) Assignee: Samsung Electronics Co., Ltd., Suwon-si (KR)

(21) Appl. No.: 19/233,528

(22) Filed: Jun. 10, 2025

(30) Foreign Application Priority Data
Sep. 13, 2024 (KR) 10-2024-0126200

(51) Int. Cl. H01L 23/538; H01L 23/00; H01L 23/31; H01L 23/498

(52) U.S. Cl. CPC H10W 70/611; H10W 70/685; H10W 74/114; H10W 90/701; H10W 72/072; H10W 72/252

(57) ABSTRACT

A semiconductor package may include an insulating layer covering a lower redistribution layer and having via holes exposing at least a portion of the lower redistribution layer, a semiconductor chip on the lower redistribution structure and including connection terminals, connecting structures, first pad layers between the connecting structures and the connection terminals, and connection bumps connecting the connection terminals of the semiconductor chip and the first pad layers. The connecting structures may include a first thin film layer extending along inner walls of the via holes of the insulating layer, a conductive connection portion on the first thin film layer, and a second thin film layer on the conductive connection portion. The connecting structures may electrically connect the connection terminals to the lower redistribution layer. An upper surface of the lower redistribution structure and an upper surface of the conductive connection portion may be coplanar.

### CROSS-REFERENCE TO RELATED APPLICATION(S)

This application claims the benefit under 35 USC 119(a) of Korean Patent Application No. 10-2024-0126200 filed on Sep. 13, 2024 in the Korean Intellectual Property Office, the entire disclosure of which is incorporated herein by reference for all purposes.

### BACKGROUND

Inventive concepts relate to a semiconductor package including a pad layer and/or a method of manufacturing the same.

As the input/output terminals of highly integrated semiconductor chips become smaller, semiconductor packages using flip-chip mounting methods that connect semiconductor chips and redistribution substrates using solder bumps are being developed. The presence or absence of defects (for example, dimples) in the pad layer in contact with solder bumps may affect the reliability and/or yield of the semiconductor package.

### SUMMARY

Example embodiments provide a semiconductor package having improved reliability and/or yield.

Example embodiments provide a method of manufacturing a semiconductor package having improved reliability and/or yield.

According to example embodiments, a semiconductor package may include a lower redistribution structure including a lower redistribution layer and an insulating layer covering the lower redistribution layer, the insulating layer having via holes exposing at least a portion of the lower redistribution layer; a semiconductor chip on the lower redistribution structure, the semiconductor chip including connection terminals; a plurality of posts on the lower redistribution structure around the semiconductor chip; a molded layer covering the plurality of posts and the semiconductor chip; connecting structures including a first thin film layer extending along inner walls of the via holes of the insulating layer, a conductive connection portion on the first thin film layer and filling the via holes, and a second thin film layer on the conductive connection portion, the connecting structures electrically connecting the connection terminals and the plurality of posts to the lower redistribution layer; first pad layers between the connecting structures and the connection terminals; connection bumps connecting the connection terminals of the semiconductor chip and the first pad layers to each other; and external connection bumps below the lower redistribution structure and electrically connected to the lower redistribution layer. An upper surface of the lower redistribution structure and an upper surface of the conductive connection portion may be coplanar. The conductive connection portion may include a first material. The first pad layers may include a second material. The second material may be different from the first material.

According to example embodiments, a semiconductor package may include a lower redistribution structure including a lower redistribution layer and an insulating layer covering the lower redistribution layer, the insulating layer having via holes exposing at least a portion of the lower redistribution layer; a semiconductor chip on the lower redistribution structure, the semiconductor chip including connection terminals; connecting structures including a first thin film layer extending along inner walls of the via holes of the insulating layer, a conductive connection portion on the first thin film layer and filling the via holes, the connecting structures electrically connecting the connection terminals to the lower redistribution layer; first pad layers between the connecting structures and the connection terminals; and connection bumps connecting the connection terminals of the semiconductor chip and the first pad layers to each other. The lower redistribution layer includes a first lower redistribution layer adjacent to the connecting structures and a second lower redistribution layer below the first lower redistribution layer. A first gap may be between a surface of the lower redistribution structure and an upper surface of the first lower redistribution layer. A second gap may be between a lower surface of the first lower redistribution layer and an upper surface of the second lower redistribution layer. The first gap may be smaller than the second gap.

According to example embodiments, a method of manufacturing a semiconductor package may include forming a lower redistribution structure on a carrier substrate, the lower redistribution structure including a lower redistribution layer and an insulating layer, the insulating layer having via holes exposing at least a portion of the lower redistribution layer; forming a first seed layer and a preliminary connection portion on the first seed layer, the first seed layer extending along inner walls of the via holes; forming a conductive connection portion by cutting a surface of the preliminary connection portion; and forming a second seed layer and first pad layers on the second seed layer, the second seed layer extending along an upper surface of the conductive connection portion.

### BRIEF DESCRIPTION OF DRAWINGS

The above and other aspects, features, and advantages of inventive concepts will be more clearly understood from the following detailed description, taken in conjunction with the accompanying drawings, in which:

FIG. 1A is a cross-sectional view of a semiconductor package according to an example embodiment, and FIG. 1B is a partial enlarged view of area ‘A’ of FIG. 1A;

FIG. 2 is a cross-sectional view of a semiconductor package according to an illustrative modified example;

FIG. 3A is a cross-sectional view of a semiconductor package according to an example embodiment, and FIG. 3B is a partial enlarged view of area ‘A’ of FIG. 3A;

FIG. 4 is a cross-sectional view of a semiconductor package according to an illustrative modified example;

FIG. 5 is a cross-sectional view of a semiconductor package according to an illustrative modified example;

FIG. 6 is a cross-sectional view of a semiconductor package according to an example embodiment;

FIG. 7 is a cross-sectional view of a semiconductor package according to an example embodiment;

FIGS. 8A to 8G are drawings illustrating a process of manufacturing a semiconductor package according to an example embodiment; and

FIGS. 9A to 9C are drawings illustrating a process of manufacturing a semiconductor package according to an example embodiment.

### DETAILED DESCRIPTION

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

Hereinafter, example embodiments will be described with reference to the attached drawings. Unless otherwise specifically stated, in this specification, terms such as “upper portion,” “upper surface,” “lower portion,” “lower surface,” “side,” “side surface,” and the like are based on the drawings and may actually vary depending on the direction in which the components are disposed.

In addition, ordinal numbers such as “first,” “second,” “third,” and the like may be used as labels for specific elements, steps, directions, and the like to distinguish various elements, steps, directions, and the like. Terms that are not described using “first,” “second,” or the like in the specification may still be referred to as “first” or “second” in the claims. In addition, the term (for example, “first” in a particular claim) that is referenced by a specific ordinal number may be described elsewhere with a different ordinal number (for example, “second” in the specification or another claim).

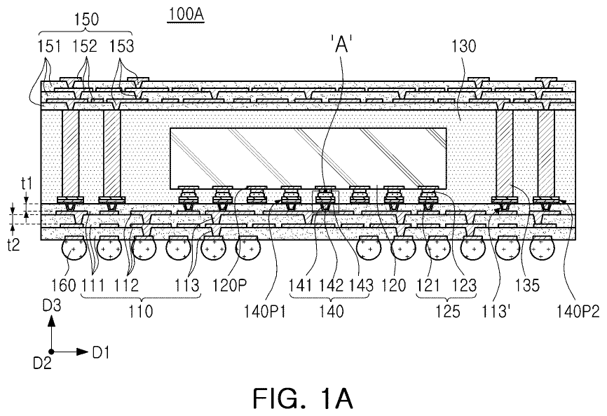

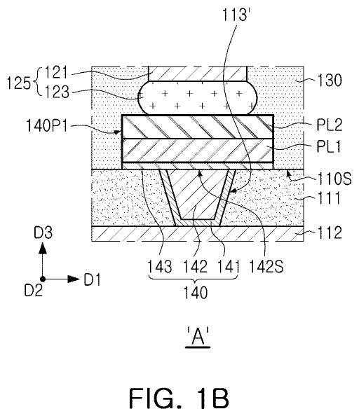

FIG. 1A is a cross-sectional view of a semiconductor package 100A according to an example embodiment, and FIG. 1B is a partially enlarged view of area ‘A’ of FIG. 1A.

Referring to FIGS. 1A and 1B, the semiconductor package 100A according to an example embodiment may include a lower redistribution structure 110, a semiconductor chip (or ‘chip structure’) 120, connecting structures 140, and first pad layers 140P1. According to an example embodiment, the semiconductor package 100A may further include an upper redistribution structure 150, a plurality of posts 135, a molded layer 130, second pad layers 140P2, and/or external connection bumps 160.

The lower redistribution structure 110 is a support substrate on which a semiconductor chip 120 is mounted, and may include an insulating layer 111, lower redistribution layers 112, and a lower redistribution via 113.

The insulating layer 111 may include an insulating resin. The insulating resin may include a thermosetting resin such as an epoxy resin, a thermoplastic resin such as a polyimide, or a resin impregnated with an inorganic filler or the like, for example, a prepreg, an Ajinomoto Build-up Film (ABF), FR-4, or a Bismaleimide-Triazine (BT). For example, the insulating layer 111 may include a photosensitive resin such as a Photo-Imageable Dielectric (PID). The insulating layer 111 may include a plurality of insulating layers that are stacked in a vertical direction D3. Depending on the process, the boundaries between the plurality of insulating layers may be unclear.

The lower redistribution layer 112 is disposed in the insulating layer 111 and may redistribute the connection terminal 120P of the chip structure 120. The lower redistribution layer 112 may include a metal including, for example, copper (Cu), aluminum (Al), silver (Ag), tin (Sn), gold (Au), nickel (Ni), lead (Pb), titanium (Ti), or alloys thereof. The lower redistribution layer 112 may perform various functions depending on the design. For example, the lower redistribution layer 112 may include a ground pattern, a power pattern, and a signal pattern. In this case, the signal pattern may be defined as a transmission path of various signals, for example, a data signal, excluding the ground pattern, the power pattern, or the like. The lower redistribution layer 112 may include more or fewer redistribution layers than those illustrated in the drawing.

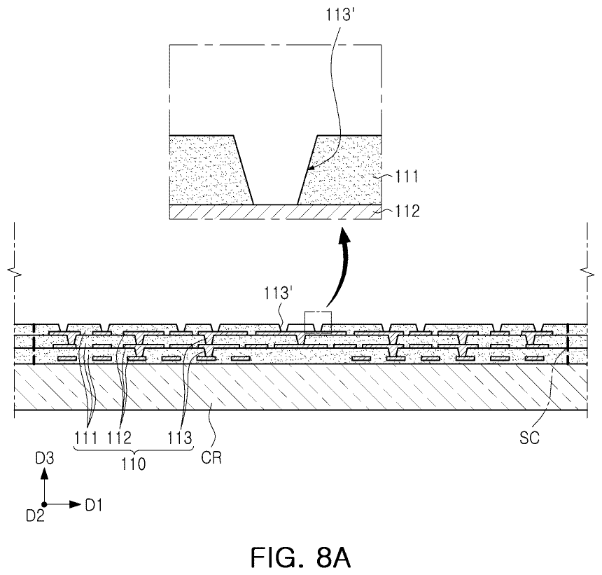

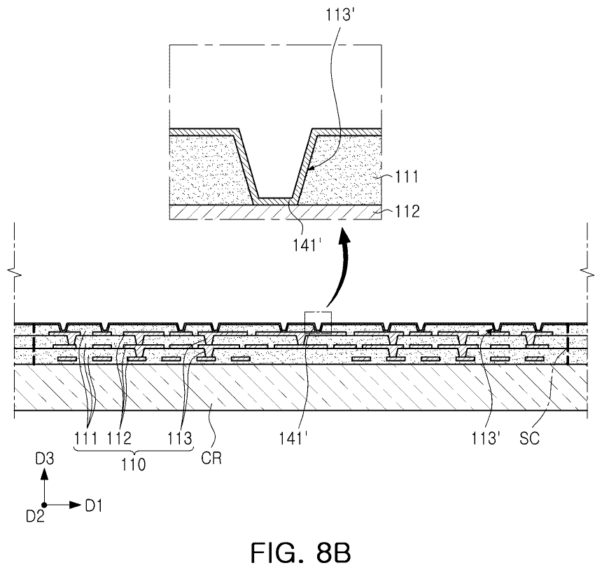

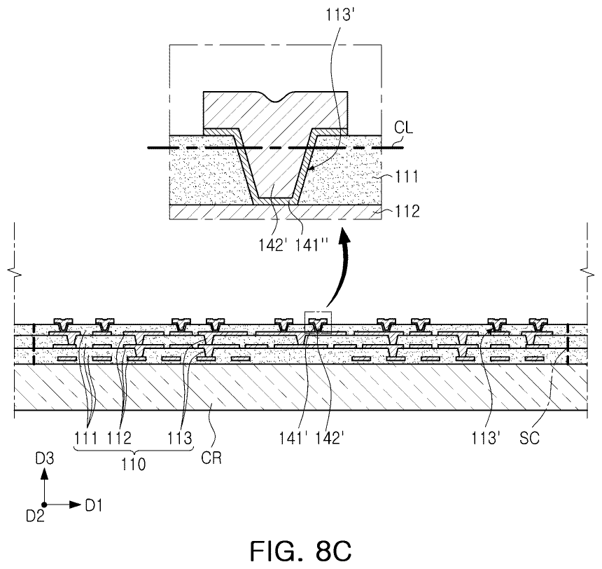

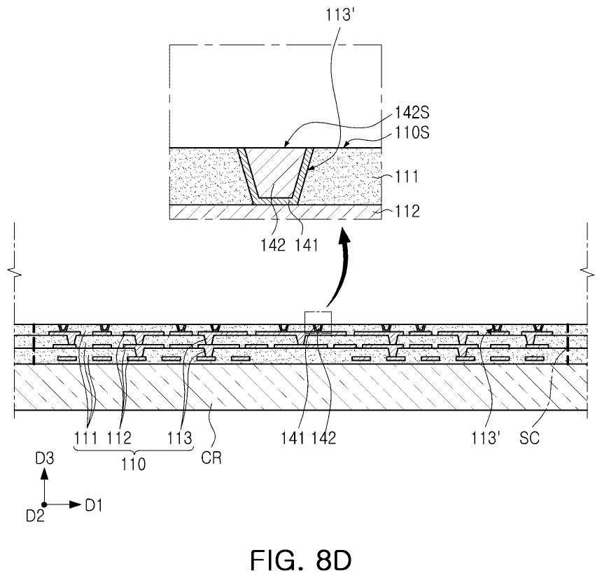

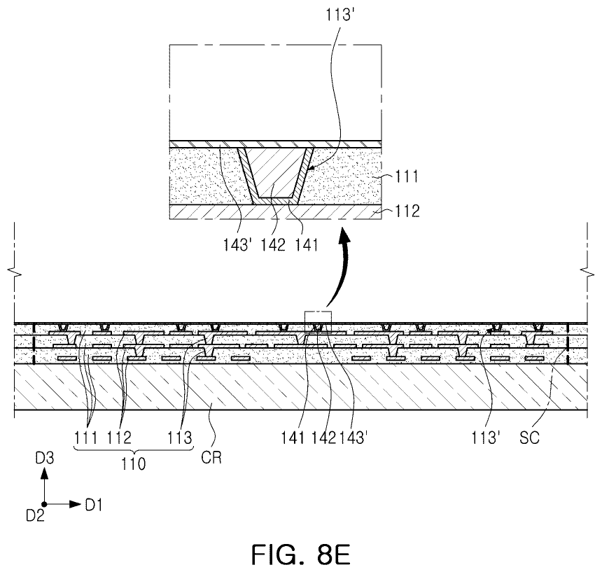

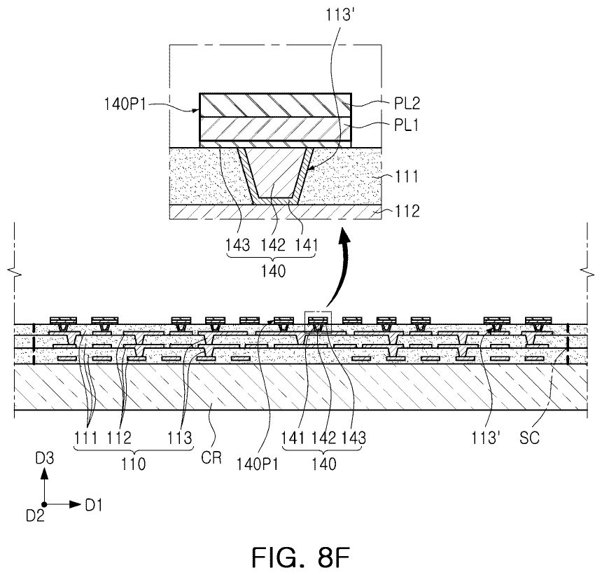

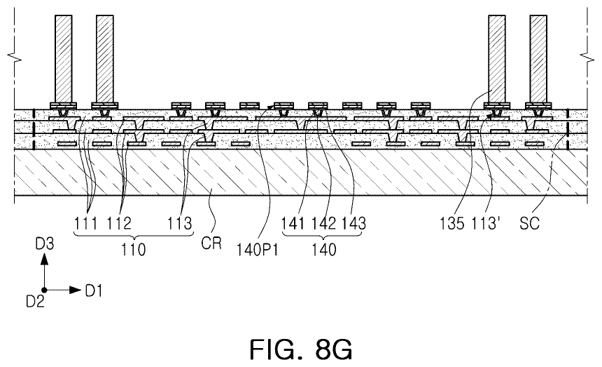

The lower redistribution layer 112 may be electrically connected to the connection terminals 120P and the plurality of posts 135 through the connecting structures 140 and the pad layers 140P1 and 140P2. The first pad layers 140P1 may have a larger width than the connecting structures 140. For example, a first horizontal width of each of the first pads 140P1 may be larger than a second horizontal width of each of the connecting structures 140. The first pad layers 140P1 may be arranged on the connecting structures. The planar shapes of the connecting structures 140 and the first pad layers 140P1 may be circular or polygonal. The lower redistribution layer 112 may include a first lower redistribution layer adjacent to the connecting structures 140, and a second lower redistribution layer below the first lower redistribution layer. The first gap t1 between the pad layers 140P1 and 140P2 and the first lower redistribution layer may be smaller than the second gap t2 between the first lower redistribution layer and the second lower redistribution layer. The first gap may have a relatively small gap due to the surface cutting process (e.g., planarization) described below (see FIGS. 8C and 8D).

The first gap t1 and the second gap t2 may be in the range of about 1 μm to 6 μm. If the first gap t1 and the second gap t2 are less than 1 μm, it may be difficult for the connecting structures 140 to be electrically separated from the lower redistribution layer 112 by the insulating layer 111, and the insulating layer 111 may be separated, thereby exposing the first lower redistribution layer externally. If the first gap t1 and the second gap t2 exceed 6 μm, the length of the via hole 113′ may become longer, which may lower electrical characteristics and increase costs. In addition, the conductive connection portion 142 in the connecting structure 140 may not be properly plated. Highly integrating semiconductor chips may reduce the weight of the product to form a thinner thickness, but if the first gap t1 and the second gap t2 between the lower redistribution layers exceed 6 μm, the amount of the insulating layer 111 may increase, which may cause the weight of the product to become heavier and the thickness to become thicker.

According to example embodiments, during the surface cutting process, the upper portion of the lower redistribution structure 110 may be cut, so that the first gap t1 may become smaller than the second gap t2. For example, the first gap t1 may be about 2 μm, and the second gap t2 may be about 5 μm. The amount of the insulating layer 111 located on the top of the lower redistribution structure 110 included in the semiconductor product is reduced by the surface cutting process, so that the weight of the product may be relatively lighter and the thickness thereof may be thinner than before.

The lower redistribution via 113 may extend within the insulating layer 111 and be electrically connected to the lower redistribution layer 112. For example, the lower redistribution via 113 may interconnect lower redistribution layers 112 of different levels. The lower redistribution via 113 may include a signal via, a ground via, and a power via. The lower redistribution via 113 may include a metal material including, for example, copper (Cu), aluminum (Al), silver (Ag), tin (Sn), gold (Au), nickel (Ni), lead (Pb), titanium (Ti), or alloys thereof. The lower redistribution via 113 may be a filled via in which a metal material is filled inside the via hole or a conformal via in which a metal material extends along the inner wall of the via hole.

The semiconductor chip 120 may be placed on the first pads 140P1 and may include connection terminals 120P electrically connected to the first pads 140P1 and the lower redistribution layer 112. The connection terminals 120P may be electrically connected to the lower redistribution layer 112 through connection bumps 125. The connection bumps 125 may include a pillar portion 121 that contacts the connection terminals 120P and a solder portion 123 that is placed below the pillar portion 121. The pillar portion 121 may include copper (Cu) or an alloy of copper (Cu), and the solder portion 123 may include a low-melting-point metal, for example, tin (Sn) or an alloy including tin (Sn). According to an example embodiment, the connection bumps 125 may include only one of the pillar portion 121 and the solder portion 123. According to an example embodiment, an underfill layer may be disposed between the semiconductor chip 120 and the lower redistribution structure 110. The underfill layer may have a capillary underfill (CUF) structure, but is not limited thereto. The underfill layer may also have a molded underfill (MUF) structure integrated with the molded layer 130.

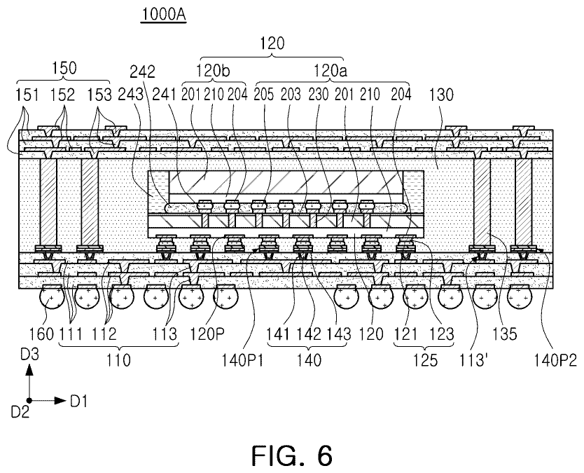

The semiconductor chip 120 may include a semiconductor wafer and an integrated circuit (IC) made of a semiconductor element such as silicon or germanium, or a compound semiconductor such as silicon carbide (SiC), gallium arsenide (GaAs), indium arsenide (InAs), and indium phosphide (InP). The semiconductor chip 120 may be a bare semiconductor chip without a separate bump or interconnection layer formed thereon, but is not limited thereto, and may also be a packaged type semiconductor chip. The semiconductor chip 120 may include a logic circuit (or ‘logic chip’) such as a central processor (CPU), a graphic processor (GPU), a field programmable gate array (FPGA), an application processor (AP), a digital signal processor, an encryption processor, a microprocessor, a microcontroller, an analog-to-digital converter and an application-specific IC (ASIC), or a memory circuit (or ‘memory chip’) including volatile memory such as dynamic RAM (DRAM) and static RAM (SRAM), and nonvolatile memory such as phase change RAM (PRAM), magnetic RAM (MRAM), resistive RAM (RRAM), and flash memory. According to an example embodiment, the semiconductor chip 120 may be a package structure including a plurality of semiconductor chips, which will be described later with reference to FIG. 6.

The upper redistribution structure 150 may be disposed on the molded layer 130 and may include an upper insulating layer 151, an upper redistribution layer 152, and an upper redistribution via 153.

The upper insulating layer 151 may include a thermosetting resin such as an epoxy resin, a thermoplastic resin such as a polyimide, or a resin impregnated with an inorganic filler, such as prepreg, ABF, FR-4, or BT. For example, the upper insulating layer 151 may include a photosensitive resin such as PID. The upper insulating layer 151 may include a plurality of insulating layers laminated in a vertical direction D3. The upper insulating layer 151 may include more or fewer insulating layers than those illustrated in the drawing. Depending on the process, the boundary between the plurality of insulating layers may be unclear.

The upper redistribution layer 152 may be disposed on and within the upper insulating layer 151. The upper redistribution layer 152 may include a metal, for example, copper (Cu), aluminum (Al), silver (Ag), tin (Sn), gold (Au), nickel (Ni), lead (Pb), titanium (Ti), or alloys thereof. The upper redistribution layer 152 may include a ground pattern, a power pattern, and a signal pattern according to a design. The upper redistribution layer 152 may include more or fewer redistribution layers than those illustrated in the drawing. According to an example embodiment, a barrier film may be formed on a pad portion of an uppermost upper redistribution layer 152. The barrier film may include, for example, nickel (Ni), gold (Au), or alloys thereof.

The upper redistribution via 153 may extend within the upper insulating layer 151 and be electrically connected to the upper redistribution layer 152. The upper redistribution via 153 may interconnect upper redistribution layers 152 at different levels. The upper redistribution via 153 may include a metal material, for example, copper (Cu), aluminum (Al), silver (Ag), tin (Sn), gold (Au), nickel (Ni), lead (Pb), titanium (Ti), or alloys thereof. The upper redistribution via 153 may be a filled via in which a metal material is filled inside the via hole or a conformal via in which a metal material extends along the inner wall of the via hole.

A plurality of posts 135 may be disposed on the second pad layers 140P2. The plurality of posts 135 may electrically connect the lower redistribution layer 112 and the upper redistribution layer 152. The plurality of posts 135 may include copper (Cu), nickel (Ni), titanium (Ti), lead (Pb), aluminum (Al), silver (Ag), gold (Au), platinum (Pt), or alloys thereof. A plurality of posts 135 may extend in a vertical direction D3 within the molded layer 130. The plurality of posts 135 may have a cylindrical shape, but is not limited thereto.

The molded layer 130 is disposed on the lower redistribution structure 110 and may cover respective at least portions of the plurality of posts 135 and the semiconductor chip 120. The molded layer 130 may include, for example, a thermosetting resin such as an epoxy resin, a thermoplastic resin such as a polyimide, or a prepreg, ABF, FR-4, BT, Epoxy Molding Compound (EMC), or the like. The molded layer 130 may surround the plurality of posts 135.

The connecting structure 140 is disposed on the upper surface 110S of the lower redistribution structure 110 and may include a first thin film layer 141, a conductive connection portion 142, and a second thin film layer 143.

The first thin film layer 141 may be disposed between the lower redistribution layer 112, the insulating layer 111, and the conductive connection portion 142. The first thin film layer 141 may be in contact with the side and lower surfaces of the conductive connection portion 142, the side surface of the via hole 113, and the lower surface of the second thin film layer 142. The first thin film layer 141 may extend along the inner wall of the via holes 113 of the insulating layer 111. The first thin film layer 141 may include copper (Cu), nickel (Ni), titanium (Ti), lead (Pb), aluminum (Al), silver (Ag), gold (Au), platinum (Pt), tungsten (W), or alloys thereof. For example, the first thin film layer 141 may include titanium (Ti), copper (Cu), and alloys thereof.

The conductive connection portion 142 may be disposed between the first thin film layer 141 and the second thin film layer 143. The conductive connection portion 142 may have a shape in which the width gradually decreases toward the lower redistribution layer 112. The conductive connection portion 142 may include copper (Cu), nickel (Ni), titanium (Ti), lead (Pb), aluminum (Al), silver (Ag), gold (Au), platinum (Pt), tungsten (W), or alloys thereof. For example, the conductive connection portion 142 may include copper (Cu) or an alloy thereof.

According to an example embodiment, to form a connecting structure 140 from which a dimple has been removed, the connecting structure 140 and the insulating layer 111 may share a flat surface formed by a surface cutting process (see FIG. 8D), such as a planarization process. For example, the upper surface 110S of the lower redistribution structure provided by the insulating layer 111, the upper surface 142S of the conductive connection portion 142, and the upper surface of the first thin film layer 141 may be coplanar.

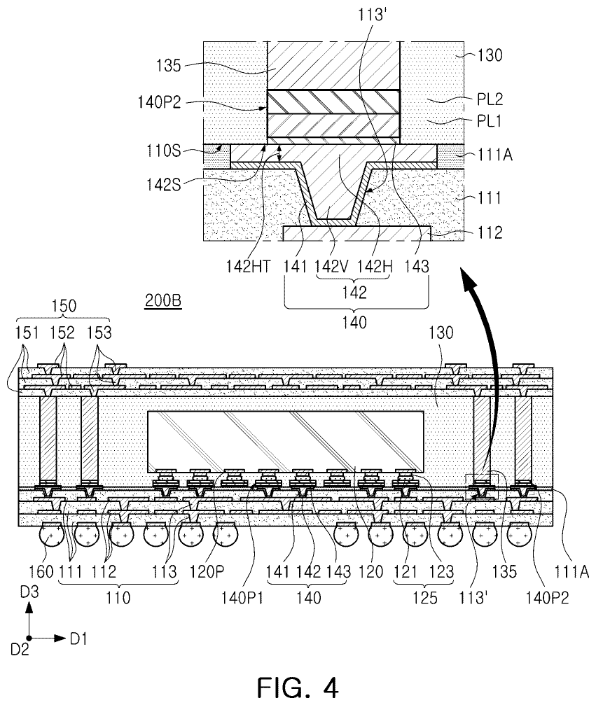

The second thin film layer 143 may be disposed between the first pad layer 140P1, the insulating layer 111, and the conductive connection portion 142. The second thin film layer 143 may be in contact with the upper surface of the conductive connection portion 142, the upper surface of the insulating layer 111, and the upper surface of the first thin film layer 141. The second thin film layer 143 may extend from the upper surface of the conductive connection portion 142 to the upper surface of the insulating layer 111 around the via holes 113′. In some embodiments, the width of the second thin film layer 143 may be greater than the width of the conductive connection portion 142 (see the example embodiment of FIG. 1A). In some embodiments, the width of the second thin film layer 143 may be equal to or less than the width of the conductive connection portion 142 (see the example embodiment of FIG. 4). The second thin film layer 143 may include copper (Cu), nickel (Ni), titanium (Ti), lead (Pb), aluminum (Al), silver (Ag), gold (Au), platinum (Pt), tungsten (W), or alloys thereof. For example, the second thin film layer 143 may include titanium (Ti) and an alloy thereof.

According to an example embodiment, by introducing first pad layers 140P1 between the connection bumps 125 and the connecting structures 140, the connection with the semiconductor chip 120 may be improved, unevenness on the surface of the connecting structures 140 may be removed, and the adhesion between the connection bumps 125 of the semiconductor chip 120 and the lower redistribution structure 110 may be improved. In addition, cracks caused by gaps between the conductive connection portion 142 and the solder portion 123 that occur during the process of attaching the connection bumps 125 on the connecting structures 140 may be limited and/or prevented, and the yield and reliability of the semiconductor package 100 may be improved.

In an example embodiment, the width of the first pad layers 140P1 may be greater than the width of the upper surface of the conductive connection portion 142. Although not illustrated, the width of the first pad layers 140P1 may be substantially equal to the width of the upper surface of the conductive connection portion 142. For example, the first pad layers 140P1 may limit and/or prevent diffusion and occurrence of Kirkendall voids between the solder portion 123 (for example, tin (Sn)) and the conductive connection portion 142 (for example, copper (Cu)) by blocking contact between the conductive connection portion 142 and the solder portion 123. When the width of the first pad layers 140P1 is substantially equal to the width of the upper surface of the conductive connection portion 142, the first pad layers 140P1 may limit and/or prevent diffusion and occurrence of Kirkendall voids between the solder portion 123 (for example, tin (Sn)) and the conductive connection portion 142 (for example, copper (Cu)). In some embodiments, the widths of the first pad layers 140P1 may be greater than the width of the upper surface of the conductive connection portion 142. The difference between the width of the first pad layers 140P1 and the width of the upper surface of the conductive connection portion 142 may be in the range of about 1 μm to 5 μm, and if the difference is less than 1 μm, the solder portion 123 (for example, tin (Sn)) may flow along the side of the first pad layer 140P1 and penetrate between the second thin film layer 143 and the insulating layer 111. If the difference exceeds 5 μm, the gap between the first pad layers 140P1 may be relatively narrow, so that the first pad layers 140P1 may overlap, which may increase the cost.

According to an example embodiment, by introducing second pad layers 140P2 between the plurality of posts 135 and the connecting structures 140, the connection with the upper redistribution layer 152 may be improved, the unevenness on the surface of the connecting structures 140 may be removed, and the bonding area between the plurality of posts 135 and the lower redistribution structure 110 may be increased. The width of the second pad layers 140P2 may be larger than the width of the upper surface of the conductive connection portion 142. If the width of the second pad layers 140P2 is smaller than the width of the upper surface of the conductive connection portion 142, it may be difficult to electrically connect with the plurality of posts 135.

The first pad layers 140P1 and the second pad layers 140P2 may include or be composed of a single-layer or multi-layer metal layer. The first pad layers 140P1 and the second pad layers 140P2 may include a material for limiting and/or preventing diffusion of solder, for example, nickel (Ni), gold (Au), or alloys thereof. According to an example embodiment, the first pad layers 140P1 and the second pad layers 140P2 may each include a first metal layer PL1 connected to the second thin film layer 143 and a second metal layer PL2 disposed between the first metal layer PL1 and the connection bump 125. For example, the first metal layer PL1 may include nickel (Ni) or an alloy thereof, and the second metal layer PL2 may include gold (Au) or an alloy thereof. According to an example embodiment, the second metal layer PL2 may be omitted or formed of a metal other than the above-described metal. The width of the second metal layer PL2 may be the same as the width of the second thin film layer 143 and the width of the first metal layer PL1.

External connection bumps 160 may be disposed below the lower redistribution structure 110. The external connection bumps 160 may be electrically connected to the lower redistribution layer 112. The semiconductor package 100A may be connected to an external device such as a module substrate, a system board, or the like through the external connection bumps 160. The external connection bumps 160 may include a low-melting point metal, for example, tin (Sn) or an alloy (for example, Sn—Ag—Cu) including tin (Sn). According to an example embodiment, the external connection bumps 160 may have a shape in which a pillar and a ball are combined. According to an example embodiment, an Under Bump Metal (UBM) structure may be placed between the external connection bumps 160 and the lower redistribution layer 112. The UBM structure may include a metal material including, for example, copper (Cu), aluminum (Al), silver (Ag), tin (Sn), gold (Au), nickel (Ni), lead (Pb), titanium (Ti), or alloys thereof.

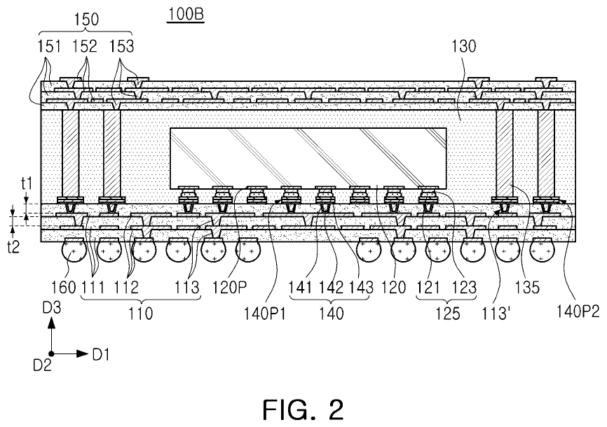

FIG. 2 is a cross-sectional view of a semiconductor package 100B according to an illustrative modified example.

Referring to FIG. 2, the semiconductor package 100B of a modified example may have the same or similar features as those described with reference to FIGS. 1A and 1B, except that the first gap t1 is equal to or greater than the second gap t2.

In a modified example, a first gap t1 between a surface of the lower redistribution structure and an upper surface of the first lower redistribution layer may be substantially equal to or larger than a second gap t2 between a lower surface of the first lower redistribution layer and an upper surface of the second lower redistribution layer. To limit and/or prevent the pad layers 140P1 and 140P2 and the first lower redistribution layer from being excessively close to each other, an insulating layer 111 may be formed thicker on an upper surface of the first lower redistribution layer during an insulating layer forming process described below (see FIG. 8A), and a surface cutting process (see FIGS. 8C and 8D) may be performed, thereby expanding the first gap t1 between the pad layers 140P1 and 140P2 and the first lower redistribution layer.

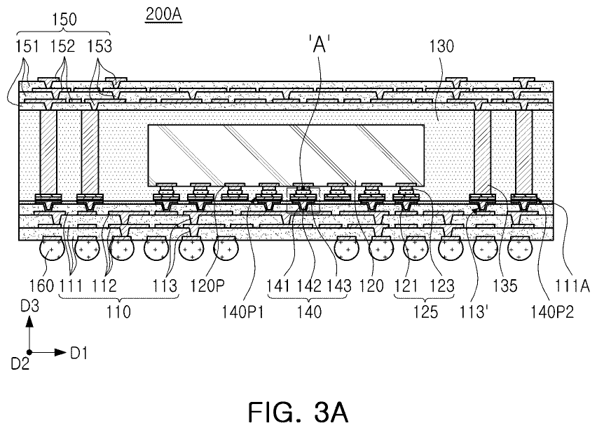

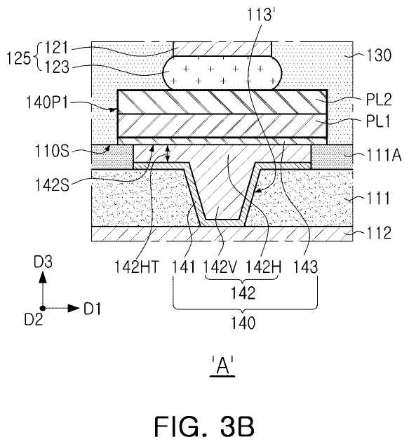

FIG. 3A is a cross-sectional view of a semiconductor package 200A according to an example embodiment, and FIG. 3B is a partial enlarged view of an area ‘A’ of FIG. 3A.

Referring to FIGS. 3A and 3B, the semiconductor package 200A of an example embodiment may have the same or similar features as those described with reference to FIGS. 1A to 2, except for the structure of the connecting structures 140 and the dielectric layer 111A.

In an example embodiment, the semiconductor package 200A may further include the connecting structures 140 and the dielectric layer 111A of a modified structure.

The lower redistribution structure 110 may further include the dielectric layer 111A.

The dielectric layer 111A may be disposed on the insulating layer 111. The dielectric layer 111A may include an insulating resin. The insulating resin may include a thermosetting resin such as an epoxy resin, a thermoplastic resin such as a polyimide, or a resin impregnated with an inorganic filler, such as prepreg, Ajinomoto Build-up Film (ABF), FR-4, or Bismaleimide-Triazine (BT). The dielectric layer 111A may include a different material from the insulating layer. For example, the insulating layer 111 may include a photosensitive resin such as Photo-Imageable Dielectric (PID), and the dielectric layer 111A may include a different type of insulating resin (for example, a non-photosensitive resin) from the insulating layer 111.

In the present embodiment, the conductive connection portion 142 may include a via portion 142V within the via holes and a horizontal portion 142H extending along the first thin film layer. The first thin film layer 141 may extend to the upper surface of the insulating layer 111 around the via holes 113'. The first thin film layer 141 may be disposed between the lower redistribution layer 112, the insulating layer 111, and the conductive connection portion 142. The first thin film layer 141 may be in contact with the side surface, the lower surface, and the upper surface of the conductive connection portion.

The connecting structure 140 may be disposed on the upper surface 110S of the lower redistribution structure 110 and may include the first thin film layer 141, the conductive connection portion 142, and the second thin film layer 143.

The first thin film layer 141 may be disposed between the lower redistribution layer 112, the insulating layer 111, the conductive connection portion 142, and the dielectric layer 111A. The first thin film layer 141 may be in contact with the side surface and the lower surface of the conductive connection portion 142, and the side surface of the via hole 113′. In detail, the first thin film layer 141 may be disposed between the lower surface of the horizontal portion 142H and the upper surface of the insulating layer 111, between the side surface of the via portion 142V and the via hole 113′ of the insulating layer 111, and between the lower surface of the via portion 142V and the upper surface of the lower redistribution layer 112. The first thin film layer 141 may extend along the inner walls of the via holes 113′ of the insulating layer 111 to the upper surface of the insulating layer 111 around the via holes 113′. The first thin film layer 141 may include copper (Cu), nickel (Ni), titanium (Ti), lead (Pb), aluminum (Al), silver (Ag), gold (Au), platinum (Pt), tungsten (W), or alloys thereof. For example, the first thin film layer 141 may include titanium (Ti), copper (Cu), and alloys thereof.

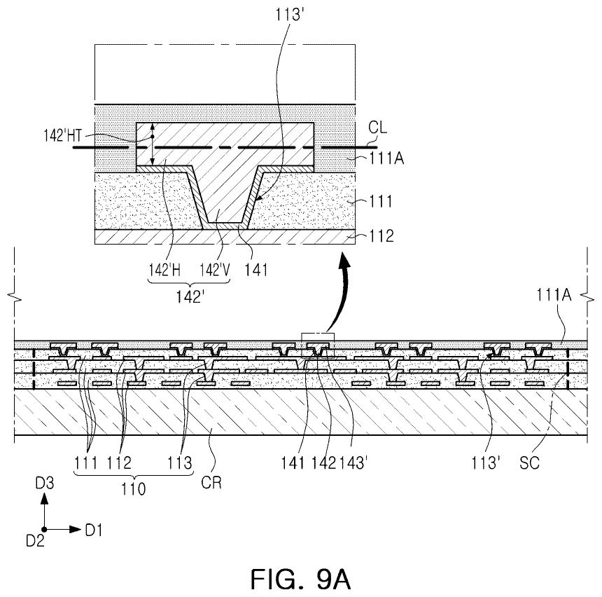

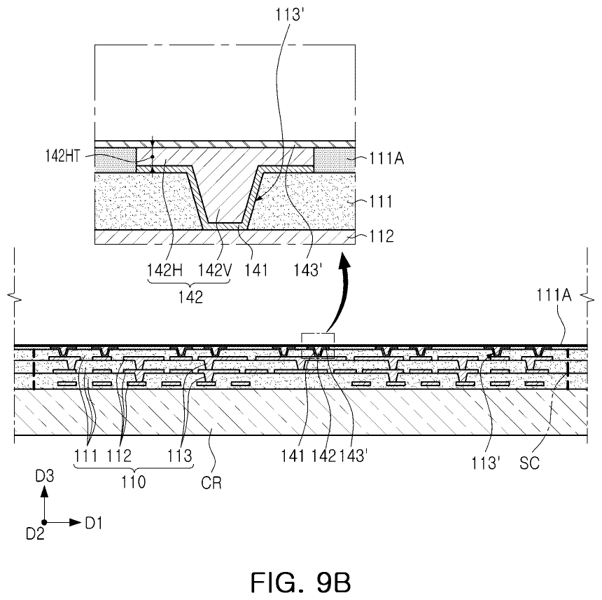

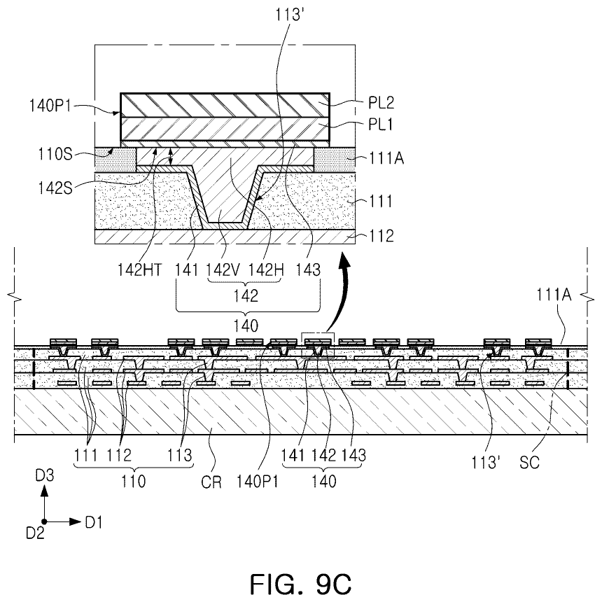

In an example embodiment, the conductive connection portion 142 may have a T-shaped pad structure. The conductive connection portion 142 may be disposed between the first thin film layer 141, the dielectric layer 111A, and the second thin film layer 143. The conductive connection portion 142 may further include a via portion 142V and a horizontal portion 142H. The via portion 142V may be positioned within the via holes 113′ and may have a shape of which the width gradually decreases toward the lower redistribution layer. The horizontal portion 142H may extend to the upper-end peripheries of the via holes 113′ along the first thin film layer. The width of the upper surface of the horizontal portion 142H may be greater than the width of the lower surface of the via portion 142V. The conductive connection portion 142 may include copper (Cu), nickel (Ni), titanium (Ti), lead (Pb), aluminum (Al), silver (Ag), gold (Au), platinum (Pt), tungsten (W), or alloys thereof. For example, the conductive connection portion 142 may include copper (Cu) or an alloy thereof. To form a connecting structure 140 from which a dimple has been removed, the horizontal portion 142H and the dielectric layer 111A may share a flat surface formed by a surface cutting process. For example, the upper surface 110S of the lower redistribution structure defined by the upper surface of the dielectric layer 111A and the upper surface 142S of the conductive connection portion 142 may be coplanar (see FIG. 9C).

The second thin film layer 143 may be disposed between the first pad layer 140P1, the dielectric layer 111A, the molded layer 130, and the conductive connection portion 142. The second thin film layer 143 may be in contact with the upper surface of the horizontal portion 142H forming the coplanar surface and the upper surface of the dielectric layer 111A. The second thin film layer 143 may extend from the upper surface of the conductive connection portion 142 to the upper surface of the dielectric layer 111A around the via holes 113. In some embodiments, the width of the second thin film layer 143 may be greater than the width of the conductive connection portion 142 (see the example embodiment of FIG. 1A). In some embodiments, the width of the second thin film layer 143 may be equal to or less than the width of the conductive connection portion 142 (see the example embodiment of FIG. 4). The second thin film layer 143 may include copper (Cu), nickel (Ni), titanium (Ti), lead (Pb), aluminum (Al), silver (Ag), gold (Au), platinum (Pt), tungsten (W), or alloys thereof. For example, the second thin film layer 143 may include titanium (Ti) and an alloy thereof.

FIG. 4 is a cross-sectional view of a semiconductor package 200B according to an illustrative variation.

Referring to FIG. 4, the semiconductor package 200B of a modified example may have the same or similar features as those described with reference to FIGS. 1A to 3B, except that the width of the second pad layer 140P2 and the width of the second thin film layer 143 are different.

In a modified example, the width of the second thin film layer 143 and the width of the second pad layers 140P2 of the semiconductor package 200B may be smaller than the width of the upper surface of the horizontal portion 142H.

Unlike the first pad layer 140P1, the width of the second thin film layer 143 of the connecting structures disposed below the second pad layer 140P2, and the width of the second pad layers 140P2, may be smaller than the width of the horizontal portion 142H. In addition, as the width of the plurality of posts 135 decreases, the gap between the plurality of posts 135 may increase. Therefore, a sufficient distance between the plurality of posts 135 may be secured to limit and/or prevent electrical interference.

The widths of the second thin film layer 143 and the second pad layer 140P2 may be formed so that the second thin film layer 143 and the pad layers 140P1 and 140P2 on some conductive connection portions 142 are smaller than the width of the conductive connection portions 142 during the process of forming the second thin film layer 142 and the pad layers 140P1 and 140P2 described later (see FIGS. 9B and 9C).

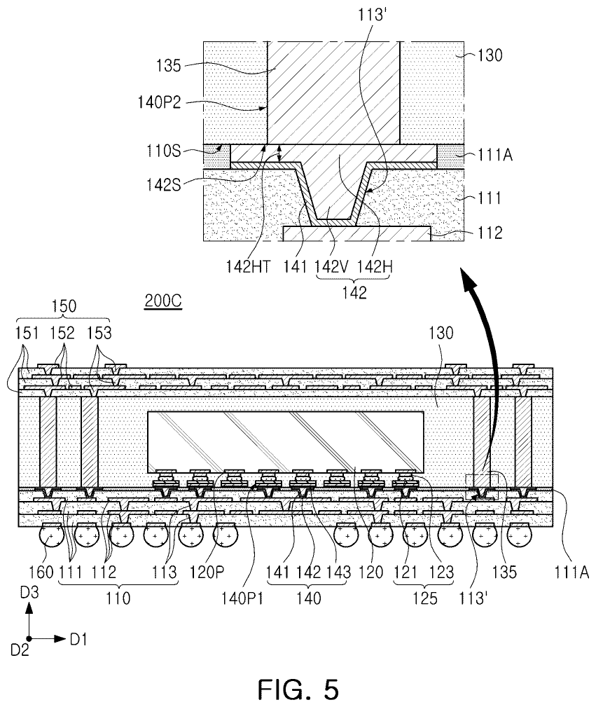

FIG. 5 is a cross-sectional view of a semiconductor package according to an illustrative modified example.

Referring to FIG. 5, a semiconductor package 200C of a modified example may have the same or similar features as those described with reference to FIGS. 3A and 3B, except that at least the plurality of posts 135 are in direct contact with the connecting structures 140.

In a modified example, the plurality of posts 135 of the semiconductor package 200C may be in direct contact with the connecting structures 140. For example, the plurality of posts 135 (for example, copper (Cu)) are disposed on the upper surface of the conductive connection portion 142 (for example, copper (Cu)), and may thus be composed of the same material. Therefore, Kirkendall voids may not occur. In addition, as the width of the plurality of posts 135 decreases, the gap between the plurality of posts 135 may increase. Therefore, electrical interference may be limited and/or prevented by securing a sufficient distance between the plurality of posts 135.

The first pad layers 140P1 are disposed between the connection bumps 125 below the semiconductor chip and the connecting structure 140 on the lower redistribution structure, but the second pad layer 140P2 may not be disposed between the conductive connection portion 142 and the plurality of posts 135.

For example, the first pad layers 140P1 are disposed between the connection bumps 125 below the semiconductor chip and the connecting structure 140 on the lower redistribution structure, but the plurality of posts 135 (for example, copper (Cu)) may be disposed without the second pad layer 140P2 on the upper surface of the conductive connection portion 142 (for example, copper (Cu)).

When plating the first pad layer 140P1, the conductive connection portion 142 at the location where the plurality of posts 135 are to be formed may be covered with a plating resist. By omitting the second pad layer 140P2, the plating process may be simplified. In addition, for example, when the conductive connection portion 142 and the plurality of posts 135 are formed of the same material, the thermal expansion coefficient, lattice constant, and the like of the material may be the same. Therefore, the occurrence of defects may be reduced and the reliability of the semiconductor package may be improved.

In the second thin film layer and pad layer forming process described below (see FIGS. 9B and 9C), some of the conductive connection portions 142 may be protected with a protective layer, the first pad layers may be formed, and the plurality of posts 135 may be formed on the connecting structure 140 so that the plurality of posts 135 may be in direct contact with the connecting structures 140.

FIG. 6 is a cross-sectional view of a semiconductor package 1000A according to an example embodiment.

Referring to FIG. 6, the semiconductor package 1000A of an example embodiment may have the same or similar features as those described with reference to FIGS. 1A to 5, except that it includes a semiconductor chip 120 having a plurality of semiconductor chips 120a and 120b embedded therein.

At least a portion (for example, ‘120a’) of the plurality of semiconductor chips 120a and 120b may include through-vias 230 that electrically connect the plurality of semiconductor chips 120a and 120b to each other. The plurality of semiconductor chips 120a and 120b may be chiplets that constitute a multi-chip module (MCM). The plurality of semiconductor chips 120a and 120b may include a central processor (CPU), a graphic processor (GPU), a field programmable gate array (FPGA), a digital signal processor (DSP), an encryption processor, a microprocessor, a microcontroller, an analog-to-digital converter, an application-specific integrated circuit (ASIC), a volatile memory, a non-volatile memory, an input/output (I/O) circuit, an analog circuit, a serial-to-parallel conversion circuit, and the like.

In an example embodiment, the semiconductor chip 120 may include a base chip 120a and at least one stacked chip 120b. For example, the base chip 120a may include a processor circuit, and the at least one stacked chip 120b may include at least one of an input/output circuit, an analog circuit, a memory circuit, and a serial-to-parallel conversion circuit for the processor circuit. The base chip 120a and the at least one stacked chip 120b may be provided in greater numbers than those illustrated in the drawing. For example, at least one of the stacked chips 120b may include two or more semiconductor chips arranged horizontally and/or vertically on a base chip 120a.

The base chip 120a and at least one stacked chip 120b may include a substrate 201, an upper protective layer 203, an upper pad 205, a circuit layer 210, a lower pad 204, and/or a through via 230. The substrate 201 may include, for example, a semiconductor element such as silicon or germanium (Ge), or a compound semiconductor such as silicon carbide (SiC), gallium arsenide (GaAs), indium arsenide (InAs), or indium phosphide (InP). The substrate 201 may have a silicon on insulator (SOI) structure. The substrate 201 may have a conductive region, for example, a well doped with impurities, or an active surface doped with impurities and an inactive surface opposite thereto. The substrate 201 may include various device isolation structures such as a shallow trench isolation (STI) structure.

The upper protective layer 203 is formed on the inactive surface of the substrate 201 and may protect the substrate 201. The upper protective layer 203 may be formed as an insulating layer such as a silicon oxide film, a silicon nitride film, a silicon oxynitride film, or the like, but the material of the upper protective layer 203 is not limited to the materials. Although not illustrated in the drawing, a lower protective layer may be further formed on the lower surface of the circuit layer 210.

The upper pad 205 may be placed on the upper protective layer 203. The upper pad 205 may include at least one of, for example, aluminum (Al), copper (Cu), nickel (Ni), tungsten (W), platinum (Pt), and gold (Au). The lower pad 204 may be placed on the lower surface of the circuit layer 210 and may include a material similar to the upper pad 205. However, the materials of the upper pad 205 and the lower pad 204 are not limited to materials. The lower pad 204 of the base chip 120a may be understood to correspond to the above-described connection terminals 120P.

The circuit layer 210 is disposed on the active surface of the substrate 201 and may include various types of elements. For example, the circuit layer 210 may include various active components and/or passive components, such as FETs such as planar Field Effect Transistors (FETs) or FinFETs, memory devices such as flash memory, Dynamic Random Access Memory (DRAMs), Static Random Access Memory (SRAMs), Electrically Erasable Programmable Read-Only Memory (EEPROMs), Phase-change Random Access Memory (PRAMs), Magnetoresistive Random Access Memory (MRAMs), Ferroelectric Random Access Memory (FeRAMs), and Resistive Random Access Memory (RRAMs), logic devices such as ANDs, ORs, and NOTs, and system Large Scale Integration (LSIs), CMOS Imaging Sensors (CISs), and Micro-Electro-Mechanical Systems (MEMS). The circuit layer 210 may include interconnecting structures electrically connected to the above-described components and interlayer insulating layers surrounding the interconnecting structures. The interlayer insulating layers may include silicon oxide or silicon nitride. The interconnecting structure may include multilayer wiring and/or vertical contacts. The interconnecting structure may connect elements of the circuit layer 210 to each other, connect elements to conductive areas of the substrate 201, or connect elements to through vias 230.

The base chip 120a may be positioned below at least one stacked chip 120b and may include through vias 230 electrically connected to at least one stacked chip 120b. The through vias 230 may penetrate the substrate 201 in a vertical direction D3 and provide an electrical path connecting the upper pad 205 and the lower pads 204. The through vias 230 may include a conductive plug and a barrier film surrounding the conductive plug. The conductive plug may include a metal, such as tungsten (W), titanium (Ti), aluminum (Al), or copper (Cu). The conductive plug may be formed by a plating process, a PVD process, or a CVD process. The barrier film may include an insulating barrier film and/or a conductive barrier film. The insulating barrier film may be formed of an oxide film, a nitride film, a carbide film, a polymer, or combinations thereof. The conductive barrier film may be disposed between the insulating barrier film and the conductive plug. The conductive barrier film may include a metal compound, such as, for example, tungsten nitride (WN), titanium nitride (TiN), or tantalum nitride (TaN). The barrier film may be formed by a PVD process or a CVD process.

The base chip 120a and at least one stacked chip 120b may be electrically connected via bumps 241. The bumps 241 may be disposed in an adhesive layer 242 between the base chip 120a and at least one stacked chip 120b. The bumps 241 include tin (Sn), indium (In), bismuth (Bi), antimony (Sb), copper (Cu), silver (Ag), zinc (Zn), lead (Pb), and/or alloys thereof, and may have a form in which a metal pillar and a solder ball are combined, depending on an example embodiment. The adhesive layer 242 surrounds the respective bumps 241 and may bond the base chip 120a and at least one stacked chip 120b. The adhesive layer 242 may be formed using a NCF (Non-Conductive Film), but is not limited thereto, and may be formed by any type of insulating film that allows a thermocompression process, for example. According to an example embodiment, the base chip 120a and at least one stacked chip 120b may be directly bonded and connected to the corresponding upper pad 205 and lower pad 204 without bumps 241.

The at least one stacked chip 120b may be sealed by a mold 243. The mold 243 may surround the outer surface of the at least one stacked chip 120b and the adhesive layer 242 on the base chip 120a. The mold 243 may include an insulating material such as EMC, for example.

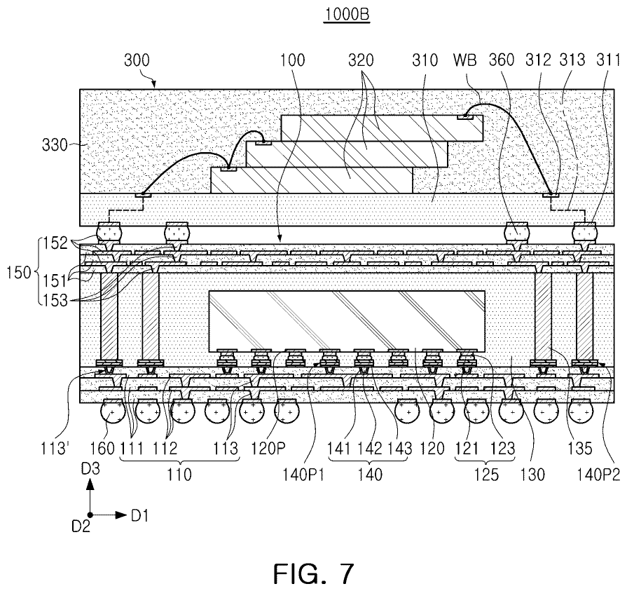

FIG. 7 is a cross-sectional view of a semiconductor package 1000B according to an example embodiment.

Referring to FIG. 7, the semiconductor package 1000B of an example embodiment may have the same or similar features as those described with reference to FIGS. 1A to 6, except that it includes a lower package 100 and an upper package 300.

Referring to FIG. 7, the semiconductor package 1000B of an example embodiment may include a lower package 100 and an upper package 300. The lower package 100 is depicted as being identical to the semiconductor package 100A depicted in FIG. 1A, but may be replaced with the semiconductor packages 100A, 100B, 200A, 200B and 200C described with reference to FIGS. 1A to 6 or semiconductor packages having similar features. The semiconductor package 1000B of the present embodiment includes a lower package 100 in which first and/or second pad layers 140P1 and 140P2 are introduced, and may implement a package-on-package structure with improved reliability and yield.

The upper package 300 may include an interconnection board 310, a semiconductor chip 320, and a sealant 330. The interconnection board 310 may include a lower pad 311 and an upper pad 312. In addition, the interconnection board 310 may include a wiring circuit 313 that electrically connects the lower pad 311 and the upper pad 312. The interconnection board 310 may be a substrate for a semiconductor package, including a printed circuit board (PCB), a ceramic substrate, a glass substrate, a tape interconnection board, or the like. For example, the interconnection board 310 may be a double-sided PCB or a multi-layer PCB.

The semiconductor chip 320 may be mounted on the interconnection board 310 by wire bonding or flip-chip bonding. For example, a plurality of semiconductor chips 320 may be stacked vertically on the interconnection board 310 and electrically connected to the upper pad 312 of the interconnection board 310 by bonding wires (WB). In one example, the semiconductor chip 320 of the upper package 300 may include a memory chip, and the semiconductor chip 120 of the lower package 100 may include an AP chip.

The sealant 330 may include a material that is the same as or similar to the molded layer 130 of the lower package 100. The upper package 300 may be physically and electrically connected to the lower package 100 by a conductive bump 360. The conductive bump 360 may include a low melting point metal, for example, tin (Sn) or an alloy including tin (Sn).

FIGS. 8A to 8G and FIG. 1A are drawings illustrating a manufacturing process of a semiconductor package according to an example embodiment. FIGS. 8A to 8G schematically illustrate a manufacturing process of a semiconductor package 100A according to an example embodiment illustrated in FIGS. 1A to 1B.

Referring to FIG. 8A, a lower redistribution structure 110 and via holes 113′ may be formed on a carrier substrate (CR). The via holes 113′ may expose at least a portion of a lower redistribution layer 112. The via holes 113′ may be formed by a photolithography process. The carrier substrate (CR) may be a temporary support including a glass wafer, a curable resin layer, or the like. The lower redistribution structure 110 may be formed at a wafer level. A plurality of lower redistribution structures 110 separated by scribe lanes (SC) may be formed on the carrier substrate (CR).

The lower redistribution structure 110 may include an insulating layer 111, a lower redistribution layer 112, and a lower redistribution via 113. The insulating layer 111 may be formed by sequentially applying and curing a photosensitive material, for example, PID. The lower redistribution layer 112 and the lower redistribution via 113 may be formed by performing an exposure process and a development process to form a via hole penetrating the insulating layer 111, and patterning a metal material on the insulating layer 111 using a plating process. Via holes 113′ may be formed on the upper surface of the lower redistribution structure 110.

Referring to FIG. 8B, a first seed layer 141′ may be formed that extends along the inner walls of the lower redistribution structure 110 and the via holes 113′. The first seed layer 141′ may be formed by a deposition process. For example, the first seed layer 141′ may be formed by a sputtering process, but is not limited thereto. The first seed layer 141′ may conformally extend along the surface of the lower redistribution structure 110. The first seed layer 141′ may be formed in a single-layer or multi-layer thin film form. The first seed layer 141′ may include copper (Cu), nickel (Ni), titanium (Ti), lead (Pb), aluminum (Al), silver (Ag), gold (Au), platinum (Pt), tungsten (W), or alloys thereof. For example, the first seed layer 141′ may include titanium (Ti), copper (Cu), and alloys thereof. The first seed layer 141′ may improve the adhesion of the conductive connection portion (or preliminary connection) in the subsequent process.

Referring to FIGS. 8C and 8D, first, the preliminary first thin film layer 141″ and the preliminary connection 142′ may be formed.

The preliminary connection 142′ may be formed on the preliminary first thin film layer 141″.

The preliminary connection 142′ may be formed by a plating process. For example, the preliminary connection 142′ may be formed by an electroplating process using the first seed layer 141′ of FIG. 8B. The preliminary connection 142′ may conformally extend along the surface of a portion of the first seed layer 141′. The preliminary connection 142′ may include, for example, copper (Cu) or an alloy thereof. At this time, the preliminary connection portion 142′ is formed on the first seed layer 141′ extending along the inner wall of the via holes 113′ of the insulating layer 111, and thus may include a recess (for example, a dimple) having a first height.

The preliminary first thin film layer 141″ may be formed by removing the plating resist layer after the plating process for the preliminary connection portion 142′ is completed, and partially removing the first seed layer 141′ of FIG. 8B. Except for the first seed layer 141′ between the preliminary connection portions 142′ and the insulating layer 111, for example, the exposed first seed layers 141′ on the surface of the insulating layer may be removed. The exposed first seed layers 141′ on the surface of the insulating layer may be removed by an etching process.

Next, the first thin film layer 141 and the conductive connection portion 142 may be formed.

The conductive connection portion 142 may be formed by cutting the surface of the preliminary connection portion 142′. At this time, the upper end of the preliminary connection portion may be cut by a second height (see the cutting line (CL) of FIG. 8C) that is greater than the first height, to remove the recess. According to an example embodiment, to remove the recess of the preliminary connection portion 142′, the preliminary connection portion 142′, the first seed layer 141′, and the insulating layer 111 may be simultaneously cut by the surface cutting process. During the surface cutting process, the preliminary connection portion 142′ and the insulating layer 111 surrounding the first seed layer 141′ may be cut together, thereby enabling the cutting process to be performed more smoothly. During the surface cutting process, the preliminary connection portion 142′ and the insulating layer 111 surrounding the first seed layer 141′ may be cut by a planarization process.

Through the surface cutting process, a portion of the first seed layer 141′ may be cut simultaneously to form the first thin film layer 141. At this time, the preliminary first thin film layer 141″ around the via hole 113′ of the insulating layer 111 may be cut. The lower redistribution layer 112 may include a first lower redistribution layer adjacent to the first thin film layer 141 and the conductive connection portion 142, and a second lower redistribution layer below the first lower redistribution layer. By cutting a portion of the insulating layer 111 simultaneously, a first gap between the upper surface of the insulating layer and the first lower redistribution layer may be smaller than a second gap between the first lower redistribution layer and the second lower redistribution layer. The upper surface 142S of the conductive connection portion 142 may be coplanar with the upper surface 111S of the cut insulating layer 111. Accordingly, the upper surface 142S of the conductive connection portion 142 and the upper surface 111S of the cut insulating layer 111 may be positioned at substantially the same level.

Referring to FIG. 8E, a second seed layer 143′ covering the surface of the insulating layer 111 and the conductive connection portion 142 may be formed. The second seed layer 143′ may be formed by a deposition process. For example, the first seed layer 141′ may be formed by a sputtering process, but is not limited thereto. The second seed layer 143′ may conformally extend along the surface of the insulating layer 111 and the conductive connection portion 142. The first seed layer 141′ may be formed in the form of a single-layer or multi-layer thin film. The first seed layer 141′ may include copper (Cu), nickel (Ni), titanium (Ti), lead (Pb), aluminum (Al), silver (Ag), gold (Au), platinum (Pt), tungsten (W), or alloys thereof. For example, the second seed layer 143′ may include titanium (Ti) or an alloy thereof. The second seed layer 143′ may improve the adhesion of the pad layers 140P1 and 140P2 in a subsequent process.

Referring to FIG. 8F, the first pad layers 140P1 and the second pad layers 140P2 may be formed. The first pad layers 140P1 and the second pad layers 140P2 may include the first metal layer PL1 and the second metal layer PL2 on the first metal layer.

The first metal layer PL1 and the second metal layer PL2 on the second thin film layer 143 may be formed by a plating process. For example, the first metal layer PL1 and the second metal layer PL2 may be formed by an electroplating process using the second thin film layer 143 as a seed. The first metal layer PL1 and the second metal layer PL2 may extend along the surface of the second thin film layer 143. The first metal layer PL1 may include, for example, nickel (Ni) or an alloy thereof. The second metal layer PL2 may include, for example, gold (Au) or an alloy thereof.

Referring to FIG. 8G, a plurality of posts 135 may be formed on the second pad layers 140P2 through a plating process. The plurality of posts 135 may include a metal material such as copper (Cu). According to an example embodiment, a metal seed layer (not illustrated) including titanium (Ti), copper (Cu), or the like may be formed on the lower surface of the plurality of posts 135.

Thereafter, as illustrated in FIG. 1A, a semiconductor chip 120 may be mounted on the lower redistribution structure 110. The semiconductor chip 120 may be mounted in a flip-chip manner. For example, the semiconductor chip 120 may be connected to the second pads 112P2 through a connection bump 125 formed on the connection pad 120P.

A molded layer 130 covering a semiconductor chip 120 and a plurality of posts 135 may be formed.

An upper redistribution structure 150 may be formed. The upper redistribution structure 150 may include upper insulating layers 151, an upper redistribution layer 152, and an upper redistribution via 153. Thereafter, a cutting process may be performed along a scribe lane (SC) to separate the unit packages, and the insulating layer 111 may be opened to form external connection bumps 160.

FIGS. 9A to 9C are drawings illustrating a manufacturing process of a semiconductor package according to an example embodiment. FIGS. 9A to 9C schematically illustrate a manufacturing process of a semiconductor package 200A according to the example embodiment illustrated in FIG. 3A.

Referring to FIG. 9A, a first thin film layer 141 and a preliminary connection portion 142′ may be formed. A preliminary connection portion 142′ may be formed on the first thin film layer 141.

The preliminary connection portion 142′ may be formed by a plating process. For example, the preliminary connection portion 142′ may be formed, but is not limited thereto. The preliminary connection portion 142′ may extend along the surface of a portion of the first seed layer 141'. The preliminary connection portion 142′ may include, for example, copper (Cu), titanium (Ti), or alloys thereof. At this time, the preliminary connection portion 142′ may further include a via portion 142′V and a preliminary horizontal portion 142′H. The preliminary horizontal portion 142′H may be formed so that the thickness of the preliminary horizontal portion 142′HT is thick enough that a recess having a first height is not formed on the preliminary connection portion 142′.

Referring to FIG. 9A, a first seed layer 141′ extending along the inner walls of the lower redistribution structure 110 and the via holes 113′ may be formed. The first seed layer 141′ may be formed in a similar manner to that described with reference to FIG. 8b. For example, the first seed layer 141′ may be formed by a sputtering process, but is not limited thereto. The first seed layer 141′ may extend conformally along the surface of the lower redistribution structure 110. The first seed layer 141′ may be formed in the form of a single-layer or multi-layer thin film. The first seed layer 141′ may include copper (Cu), nickel (Ni), titanium (Ti), lead (Pb), aluminum (Al), silver (Ag), gold (Au), platinum (Pt), tungsten (W), or alloys thereof. For example, the first seed layer 141′ may include titanium (Ti), copper (Cu), and alloys thereof. The first seed layer 141′ may improve the adhesion of a conductive connection portion (or a preliminary connection) in a subsequent process.

Referring to FIG. 9A, a first thin film layer 141 and a preliminary connection portion 142′ may be formed.

The first thin film layer 141 may be formed by partially removing the first seed layer 141′. Except for the first seed layer 141′ between the preliminary connection portions 142′ and the insulating layer 111, for example, the exposed first seed layers 141′ on the surface of the insulating layer may be removed. The exposed first seed layers 141′ on the surface of the insulating layer may be removed by an anisotropic etching process, for example, a dry etching process.

The preliminary connection portion 142′ may be formed on the first thin film layer 141. The preliminary connection portion 142′ may be formed by a plating process. For example, the preliminary connection 142′ may be formed by an electroplating process using the first seed layer 141′ of FIG. 8B. The preliminary connection 142′ may extend along the surface of a portion of the first seed layer 141′. The preliminary connection 142′ may include, for example, copper (Cu) or an alloy thereof. At this time, the preliminary connection 142′ is formed on the first seed layer 141′ extending along the inner wall of the via holes 113′ of the insulating layer 111, but the thickness of the preliminary connection 142′ may be formed thickly to form the preliminary connection 142′ that does not include a recess.

The dielectric layer 111A may be formed along the upper surface of the lower redistribution structure 110 to cover the insulating layer and the preliminary connection 142′.

Referring to FIG. 9B, a conductive connection portion 142 may be formed. The conductive connection portion may be formed by cutting the top of the preliminary connection 142′.

The top of the dielectric layer 111A may be cut simultaneously therewith. By cutting a portion of the top of the dielectric layer 111A simultaneously, the thickness 142HT of the horizontal portion may be thinner than the thickness 142′HT of the preliminary horizontal portion. The length of the dielectric layer 111A in the third direction D3 may be smaller than the first gap between the upper surface of the insulating layer and the first lower redistribution layer.

A second seed layer 143′ covering the surface of the dielectric layer 111A and the conductive connection portion 142 may be formed. The second seed layer 143′ may be formed by a deposition process. For example, the second seed layer 141′ may be formed by a sputtering process, but is not limited thereto. The second seed layer 143′ may conformally extend along the surface of the dielectric layer 111A and the conductive connection portion 142. The second seed layer 143′ may be formed in the form of a single-layer thin film. The second seed layer 143′ may include, for example, titanium (Ti). The second seed layer 143′ may improve the adhesion of the first pad layers 140P1 and the second pad layers 140P2 in a subsequent process.

Referring to FIG. 9B, the conductive connection portion 142 may be formed by cutting the surface of the preliminary connection portion 142′. At this time, the top of the preliminary connection portion may be cut by a first height (see cutting line (CL) of FIG. 9A) to adjust the thicknesses of the dielectric layer 111A and the conductive connection portion 142. According to an example embodiment, the preliminary connection portion 142′ and the dielectric layer 111A may be cut simultaneously by the surface cutting process. During the surface cutting process, the cutting process may be performed more smoothly by cutting the dielectric layer 111A surrounding the preliminary connection portion 142′ together.

The lower redistribution layer 112 may include a first lower redistribution layer adjacent to the first thin film layer 141 and the conductive connection portion 142, and a second lower redistribution layer below the first lower redistribution layer. Through a surface cutting process, a portion of the dielectric layer 111A may be cut simultaneously, thereby controlling the thickness of the dielectric layer 111A. A first gap between an upper surface of the dielectric layer 111A and the first lower redistribution layer may be smaller than a second gap between the first lower redistribution layer and the second lower redistribution layer. An upper surface 142S of the conductive connection portion 142 (see FIG. 3B) may be coplanar with an upper surface 110S (see FIG. 3B) of the lower redistribution structure defined by the upper surface of the cut dielectric layer 111A. Therefore, the upper surface 142S of the conductive connection portion 142 and the upper surface 110S of the lower redistribution structure (see FIG. 3B) defined by the upper surface of the cut dielectric layer 111A may be positioned at substantially the same level.

Subsequently, a second seed layer 143′ covering the surface of the insulating layer 111 and the conductive connection portion 142 may be formed. The second seed layer 143′ may be formed by a deposition process. For example, the first seed layer 141′ may be formed by a sputtering process, but is not limited thereto. The second seed layer 143′ may conformally extend along the surface of the insulating layer 111 and the conductive connection portion 142. The first seed layer 141′ may be formed in the form of a single-layer or multi-layer thin film. The first seed layer 141′ may include copper (Cu), nickel (Ni), titanium (Ti), lead (Pb), aluminum (Al), silver (Ag), gold (Au), platinum (Pt), tungsten (W), or alloys thereof. For example, the second seed layer 143′ may include titanium (Ti) or an alloy thereof. The second seed layer 143′ may improve the adhesion of the pad layers 140P1 and 140P2 in a subsequent process.

Referring to FIG. 9C, the first pad layers 140P1 and the second pad layers 140P2 may be formed. The first pad layers 140P1 and the second pad layers 140P2 may include the first metal layer PL1 and the second metal layer PL2 on the first metal layer.

The first metal layer PL1 and the second metal layer PL2 on the first metal layer may be formed by a plating process on the second thin film layer 143. For example, the first metal layer PL1 and the second metal layer PL2 may be formed, but are not limited thereto. The first metal layer PL1 and the second metal layer PL2 may extend along the surface of the second thin film layer 143. The first metal layer PL1 may include, for example, nickel (Ni) or an alloy thereof. The second metal layer PL2 may include, for example, gold (Au) or an alloy thereof.

The upper surface of the dielectric layer 111A may define the upper surface 110S of the lower redistribution structure. The upper surface 142S of the conductive connection portion 142 may be located at substantially the same level as the upper surface of the cut dielectric layer 111A.

As set forth above, according to example embodiments, a semiconductor package having improved reliability and yield and a method of manufacturing the same may be provided, by introducing a pad layer between a conductive connection portion and connection bumps.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While example embodiments have been illustrated and described above, it will be apparent to those skilled in the art that modifications and variations could be made without departing from the scope of inventive concepts as defined by the appended claims.

What is claimed is:

1. A semiconductor package comprising:
a lower redistribution structure including a lower redistribution layer and an insulating layer covering the lower redistribution layer, the insulating layer having via holes exposing at least a portion of the lower redistribution layer;
a semiconductor chip on the lower redistribution structure, the semiconductor chip including connection terminals;
a plurality of posts on the lower redistribution structure around the semiconductor chip;
a molded layer covering the plurality of posts and the semiconductor chip;
connecting structures including a first thin film layer extending along inner walls of the via holes of the insulating layer, a conductive connection portion on the first thin film layer and filling the via holes, and a second thin film layer on the conductive connection portion, the connecting structures electrically connecting the connection terminals and the plurality of posts to the lower redistribution layer;
first pad layers between the connecting structures and the connection terminals;
connection bumps connecting the connection terminals of the semiconductor chip and the first pad layers to each other; and
external connection bumps below the lower redistribution structure and electrically connected to the lower redistribution layer, wherein
an upper surface of the lower redistribution structure and an upper surface of the conductive connection portion are coplanar,
the conductive connection portion includes a first material,
the first pad layers include a second material, and
the second material is different from the first material.

2. The semiconductor package of claim 1, wherein
the insulating layer defines the upper surface of the lower redistribution structure, and
the conductive connection portion has a shape in which a width gradually decreases within the insulating layer as a level of the conductive connection portion becomes closer to the lower redistribution layer.

3. The semiconductor package of claim 1, further comprising:
an upper redistribution structure on the semiconductor chip, the upper redistribution structure including an upper redistribution layer; and
second pad layers between the plurality of posts and the connecting structures, wherein
the plurality of posts electrically connect the lower redistribution layer and the upper redistribution layer.

4. The semiconductor package of claim 3, wherein a width of the second pad layers is greater than a width of the upper surface of the conductive connection portion.

5. The semiconductor package of claim 3, wherein a width of the second pad layers is smaller than a width of the upper surface of the conductive connection portion.

6. The semiconductor package of claim 2, wherein
an upper surface of the first thin film layer is coplanar with the upper surface of the conductive connection portion and the upper surface of the lower redistribution structure, and
the second thin film layer contacts the upper surface of the conductive connection portion, an upper surface of the insulating layer, and the upper surface of the first thin film layer.

7. The semiconductor package of claim 1, wherein the first material includes copper (Cu) or an alloy thereof, and
the second material includes nickel (Ni), gold (Au), or alloys thereof.

8. The semiconductor package of claim 1, wherein
the first pad layers include a first metal layer and a second metal layer,
the first metal layer is on the second thin film layer and includes nickel (Ni) or an alloy thereof, and
the second metal layer disposed between the first metal layer and the connection bumps and including gold (Au) or an alloy thereof.

9. The semiconductor package of claim 1, wherein
the lower redistribution structure further includes a dielectric layer on the insulating layer and the dielectric layer defines the upper surface of the lower redistribution structure,
the first thin film layer extends to the upper surface of the insulating layer around the via holes,
the conductive connection portion includes a via portion in the via holes and a horizontal portion,
the horizontal portion extends along the first thin film layer onto the upper surface of the insulating layer, and
a side surface of the horizontal portion is surrounded by the dielectric layer.

10. The semiconductor package of claim 9, wherein
an upper surface of the horizontal portion defines the upper surface of the conductive connection portion,
the second thin film layer contacts the upper surface of the horizontal portion and an upper surface of the dielectric layer, and
the second thin film layer is spaced apart from the first thin film layer in a vertical direction.

11. The semiconductor package of claim 1, wherein a width of the first pad layers is equal to or larger than a width of the upper surface of the conductive connection portion.

12. The semiconductor package of claim 11, wherein a difference between the width of the first pad layers and the width of the upper surface of the conductive connection portion is in a range of 1 μm to 5 μm.

13. The semiconductor package of claim 11, wherein the connection bumps include tin (Sn) or an alloy thereof.

14. A semiconductor package comprising:
a lower redistribution structure including a lower redistribution layer and an insulating layer covering the lower redistribution layer, the insulating layer having via holes exposing at least a portion of the lower redistribution layer;
a semiconductor chip on the lower redistribution structure, the semiconductor chip including connection terminals;
connecting structures including a first thin film layer extending along inner walls of the via holes of the insulating layer, a conductive connection portion on the first thin film layer and filling the via holes, the connecting structures electrically connecting the connection terminals to the lower redistribution layer;
first pad layers between the connecting structures and the connection terminals; and
connection bumps connecting the connection terminals of the semiconductor chip and the first pad layers to each other, wherein
the lower redistribution layer includes a first lower redistribution layer adjacent to the connecting structures and a second lower redistribution layer below the first lower redistribution layer,
a first gap is between a surface of the lower redistribution structure and an upper surface of the first lower redistribution layer,
a second gap is between a lower surface of the first lower redistribution layer and an upper surface of the second lower redistribution layer, and
the first gap is smaller than the second gap.

15. The semiconductor package of claim 14, wherein the first gap is 1 μm or more.

16. The semiconductor package of claim 14, wherein
the connecting structures further include a second thin film layer on the conductive connection portion,
an upper surface of the conductive connection portion is coplanar with an upper surface of the insulating layer, and
the second thin film layer contacts the upper surface of the conductive connection portion, the upper surface of the insulating layer, and an upper surface of the first thin film layer.

17. A method of manufacturing a semiconductor package, the method comprising:
forming a lower redistribution structure on a carrier substrate, the lower redistribution structure including a lower redistribution layer and an insulating layer, the insulating layer having via holes exposing at least a portion of the lower redistribution layer;
forming a first seed layer and a preliminary connection portion on the first seed layer, the first seed layer extending along inner walls of the via holes;
forming a conductive connection portion by cutting a surface of the preliminary connection portion; and
forming a second seed layer and first pad layers on the second seed layer, the second seed layer extending along an upper surface of the conductive connection portion.

18. The method of claim 17, wherein
the forming the conductive connection portion includes simultaneously cutting a top of the preliminary connection portion and a top of the insulating layer, and
the upper surface of the conductive connection portion is coplanar with an upper surface of the insulating layer after the simultaneously cutting the top of the preliminary connection portion and the top of the insulating layer.

19. The method of claim 18, wherein
an upper surface of the preliminary connection portion further includes a recess having a first height, and
in the forming the conductive connection portion, a portion of the preliminary connection portion is cut,
the portion of the preliminary connection portion has a thickness corresponding to a second height from the upper surface of the preliminary connection portion, and
the second height is greater than the first height.

20. The method of claim 17, wherein
the lower redistribution structure further includes a dielectric layer on the insulating layer,
the dielectric layer covers the preliminary connection portion,
the forming the conductive connection portion includes cutting an upper surface of the preliminary connection portion and an upper surface of the dielectric layer simultaneously, and
the upper surface of the conductive connection portion is coplanar with an upper surface of the dielectric layer after the cutting the upper surface of the preliminary connection portion and the upper surface of the dielectric layer simultaneously.
